(19) United States
(12) Patent Application Publication
(10) Pub. No.: US 2021/0075312 A1
(43) Pub. Date: Mar. 11, 2021

(54) POWER SOURCE INPUT CIRCUIT AND INVERTER-INTEGRATED ELECTRIC COMPRESSOR FOR VEHICLE COMPRISING SAID CIRCUIT

(71) Applicant: SANDEN AUTOMOTIVE COMPONENTS CORPORATION, Isesaki-shi, Gunma (JP)

(72) Inventors: Hiroshi YOSHIDA, Isesaki-shi, Gunma (JP); Saori KURIBARA, Isesaki-shi, Gunma (JP); Takashi KANAI, Isesaki-shi, Gunma (JP)

(21) Appl. No.: 16/981,574

(22) PCT Filed: May 17, 2019
(86) PCT No.: PCT/JP2019/019745

§ 371 Date: Sep. 16, 2020

(30) Foreign Application Priority Data
May 24, 2018 (JP) 2018-099559

(51) Int. Cl. H02M 1/32; H02M 7/537; H02M 1/08

(52) U.S. Cl. CPC H02M 1/32; H02M 2001/0009; H02M 1/08; H02M 7/537

(57) ABSTRACT

There is provided a power source input circuit capable of suppressing an oscillation phenomenon of an input current without any trouble. The power source input circuit includes a current detection resistor 21 which detects a current on the basis of a voltage generated thereacross, and a transistor Q3 whose collector is connected to a gate of a power switching element Q2. The transistor Q3 changes the voltage of a base thereof according to the voltage generated across the current detection resistor 21 and adjusts the voltage of the gate of the power switching element Q2 to allow a constant current operation to be performed. Further, a capacitor 28 is connected between the base and collector of the transistor Q3.

### TECHNICAL FIELD

The present invention relates to a power source input circuit from a DC power source to a load, and a vehicular inverter-integrated electric compressor having the same, which limits an inrush current.

### BACKGROUND ART

For example, in an inverter-integrated electric compressor mounted on a vehicle, when the power supply from a battery (DC power source) to a load such as a DC/DC converter is turned ON/OFF, an inrush current flows to charge an output capacitor. For this reason, there has been designed a power source input circuit which uses a switching element to limit this inrush current and allows a constant current operation to be performed (refer to, for example, Patent Document 1, Patent Document 2, and Patent Document 3).

### CITATION LIST

### Patent Documents

Patent Document 1: Japanese Utility Model Application Laid-Open No. Sho 63(1988)-138879

Patent Document 2: Japanese Patent Application Laid-Open No. Hei 6(1994)-59754

Patent Document 3: Japanese Patent Application Laid-Open No. 2012-143114

### SUMMARY OF THE INVENTION

### Problems to be Solved by the Invention

However, such a conventional power source input circuit has been accompanied by a problem in that although the constant current operation of the inrush current can be achieved, the inrush current at the moment when the power supply is turned ON rises sharply, so that when a circuit having an inductance component of an EMC filter circuit or the like is provided in an input section for the purpose of noise suppression, the input current at the moment when the power supply is turned ON becomes an oscillation waveform due to the resonance between an inductance component of the filter circuit and a capacitance component of an input capacitor, whereby a peak value thereof exceeds a predetermined limit current value.

Therefore, in Patent Document 3, for example, a problem arises in that although the rise of the inrush current is moderated by a time constant circuit composed of a capacitor connected to an input electrode and a control electrode of a switch means which conducts and cuts off a conduction path from the power source to the load, a resistor connected in parallel to the capacitor, and a resistor connected in series to the control electrode of the switch means, a capacitive element having an extremely large value is required to suppress an oscillation phenomenon of the input current where the circuit having the inductance component such as the EMC filter circuit is provided in the input section, and the holding time of an output voltage after the power supply is turned OFF becomes too long, so that the specification of an ON/OFF operation is not satisfied.

The present invention has been made to solve such conventional technical problems, and aims to provide a power source input circuit capable of suppressing an oscillation phenomenon of an input current without hindrance, and an inverter-integrated electric compressor for a vehicle including the power source input circuit.

### Means for Solving the Problems

A power source input circuit of the present invention includes a power switching element connected between a DC power source and a load and is configured to change a voltage of a control electrode of the power switching element to control a current from the DC power source to the load, and is characterized in that the power source input circuit includes a current detection resistor which detects the current with a voltage generated at both ends thereof due to an inrush current, and a current limiting control element having a control electrode and a pair of main electrodes whose one main electrode is connected to the control electrode of the power switching element, and in that a voltage of the control electrode of the current limiting control element changes according to the voltage generated across the current detection resistor and thereby the current limiting control element adjusts the voltage of the control electrode of the power switching element to allow a constant current operation to be performed, and a resistive element is connected between one end of the current detection resistor and the control electrode of the current limiting control element and a capacitive element is connected between the control electrode of the current limiting control element and the one main electrode thereof.

The power source input circuit of the invention of claim 2 is characterized in that in the above invention, the power switching element is a voltage-driven switching element having a gate as the control electrode, the current limiting control element is a bipolar transistor having a base as the control electrode and a collector and an emitter as the main electrodes, the collector as the one main electrode of the current limiting control element is connected to the control electrode of the power switching element, and the capacitive element is connected between the base and collector of the current limiting control element.

The power source input circuit of the invention of claim 3 is characterized in the above respective inventions by including a switch circuit connected via a first resistor between the control electrode of the power switching element and the DC power source on the side non-connected to the power switching element, and a second resistor connected between one main electrode of the power switching element and the control electrode thereof.

The power source input circuit of the invention of claim 4 is characterized in that in the above invention, immediately after the switch circuit is made conductive, the voltage of the control electrode of the power switching element does not reach an ON voltage of the power switching element, and the voltage of the control electrode of the current limiting control element reaches an ON voltage of the current limiting control element.

The power source input circuit of the invention of claim 5 is characterized in the above respective inventions by including a filter circuit having an inductance component.

A vehicular inverter-integrated electric compressor of the invention of claim 6 is characterized by having the power source input circuit according to each invention described above, and a control circuit to control an inverter as the load.

### Advantageous Effect of the Invention

According to the present invention, in a power source input circuit which includes a power switching element connected between a DC power source and a load and changes a voltage of a control electrode of the power switching element to control a current from the DC power source to the load, it is composed of a current detection resistor which detects the current with a voltage generated at both ends thereof due to an inrush current, and a current limiting control element having a control electrode and a pair of main electrodes whose one main electrode is connected to the control electrode of the power switching element. The voltage of the control electrode of the current limiting control element changes according to the voltage generated across the current detection resistor. The current limiting control element adjusts the voltage of the control electrode of the power switching element to thereby perform a constant current operation. Further, a resistive element is connected between one end of the current detection resistor and the control electrode of the current limiting control element, and a capacitive element is connected between the control electrode of the current limiting control element and the one main electrode thereof. Therefore, the rise of the inrush current is suppressed, and even in the case where a filter circuit having an inductance component is provided as in claim 5, an oscillation phenomenon of the input current is suppressed, and the exceeding of the peak value of the input current from a limit current value can be eliminated.

Especially, by connecting the capacitive element between the control electrode of the current limiting control element and the one main electrode, it is possible to suppress the rise of the inrush current with a small capacitance value. Also, since the holding time of an output voltage when the power supply is turned OFF does not become excessively long either, the specification of an ON/OFF operation can also be satisfied without any trouble.

Specifically, for example, as in the invention of claim 2, preferably, the power switching element is constituted by a voltage-driven switching element having a gate as a control electrode, the current limiting control element is constituted by a bipolar transistor having a base as a control electrode and a collector and an emitter as main electrodes, a collector as one main electrode of the current limiting control element is connected to the control electrode of the power switching element, and a capacitive element is connected between the base and collector of the current limiting control element.

Further, as in the invention of claim 3, a switch circuit is connected via a first resistor between the control electrode of the power switching element and the DC power source on the side not connected to the power switching element, and a second resistor is connected between one main electrode of the power switching element and the control electrode thereof.

Then, as in the invention of claim 4, immediately after the switch circuit is made conductive, the voltage of the control electrode of the power switching element does not reach an ON voltage of the power switching element, and the voltage of the control electrode of the current limiting control element is set to reach an ON voltage of the current limiting control element, whereby the rise of the inrush current can be effectively suppressed.

In particular, the input current can be limited to a predetermined current value with a capacitive element having a small value connected between the control electrode of the current limiting control element and one of the main electrodes. Thus, the power source input circuit described above becomes an extremely suitable one in that when the control circuit to control the inverter of the vehicular inverter-integrated electric compressor is applied as a load as in the invention of claim 6, the power supply can be stopped without causing an excessive delay with respect to a power OFF signal.

### BRIEF DESCRIPTION OF THE DRAWINGS

FIG. 1 is an electric circuit diagram of a power source input circuit according to an embodiment to which the present invention is applied.

FIG. 2 is a diagram describing an ON/OFF signal, an input current, and a gate voltage of a power switching element Q2 in the power source input circuit of FIG. 1.

FIG. 3 is a diagram describing an ON/OFF signal, a charging current of an output capacitor, a charging voltage of the output capacitor, and a gate voltage of the power switching element Q2 in the power source input circuit of FIG. 1.

FIG. 4 is a circuit diagram where no capacitive element is provided between the base and collector of a transistor Q3 in an electric circuit of FIG. 1.

FIG. 5 is a diagram describing an ON/OFF signal, an input current, and a gate voltage of a power switching element Q2 in the case of FIG. 4.

FIG. 6 is a diagram describing an ON/OFF signal, a charging current of an output capacitor, a charging voltage of the output capacitor, and a gate voltage of the power switching element Q2 in the case of FIG. 4.

### MODE FOR CARRYING OUT THE INVENTION

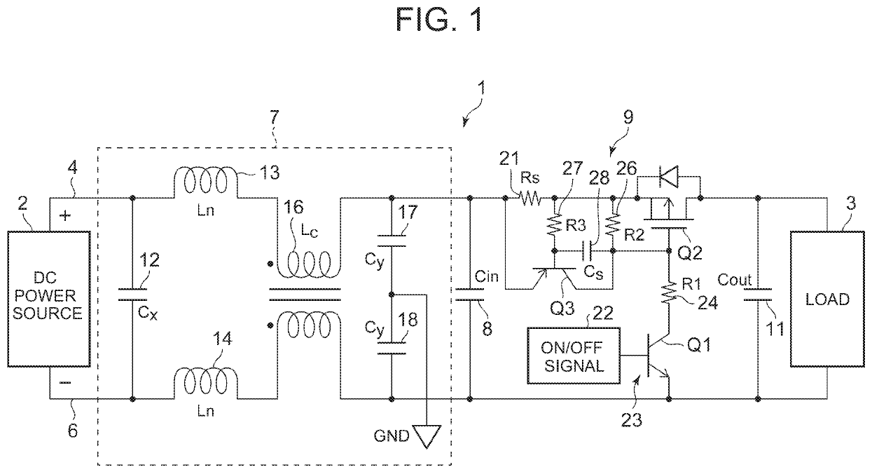

Hereinafter, embodiments of the present invention will be described in detail with reference to the drawings. FIG. 1 shows an electric circuit diagram of a power source input circuit 1 according to an embodiment to which the present invention is applied. In this figure, the power source input circuit 1 according to the embodiment is configured to supply a DC voltage from a battery (e.g., DC 12V. DC power source in the present invention) 2 mounted on a vehicle to a DC/DC converter 3 (load in the present invention) constituting a control circuit of a vehicular inverter-integrated electric compressor (not shown) mounted on the vehicle in similar fashion, and includes an EMC filter circuit 7 (example of filter circuit) connected to a positive side power source line 4 (+) and a negative side power source line 6 (−) of the battery 2, an input capacitor 8 denoted by Cin in the figure, an inrush current limiting circuit 9, and an output capacitor 11 denoted by Cout in the figure.

The above EMC filter circuit 7 is comprised of a capacitor 12 denoted by Cx in the figure, which is connected between the positive side power source line 4 and the negative side power source line 6, normal mode coils 13 and 14 denoted by Ln in the figure, which are respectively connected in series to the positive side power source line 4 and the negative side power source line b in a subsequent stage of the capacitor 12, a common mode coil 16 denoted by Lc in the figure, which is connected to the subsequent stage of these normal mode coils 13 and 14, and capacitors 17 and 18 denoted by Cy in the figure, which are respectively connected between the positive side power source line 4 and the negative side power source line 6 and the ground (GND).

The above capacitor 12 is a capacitor for reducing differential mode noise, and the capacitors 17 and 18 are capacitors for reducing common mode noise.

The input capacitor 8 is connected between the positive side power source line 4 and the negative side power source line 6 in the subsequent stage of such an EMC filter circuit 7. The inrush current limiting circuit 9 is connected between the positive side power source line 4 and the negative side power source line 6 in the subsequent stage of the input capacitor 8. The output capacitor 11 is connected between the positive side power source line 4 and the negative side power source line 6 in the subsequent stage of the inrush current limiting circuit 9.

The inrush current limiting circuit 9 to which the present invention is applied is comprised of a current detection resistor 21 having a resistance Rs, a switch circuit 23 composed of an NPN type transistor (bipolar transistor) Q1 and an ON/OFF signal circuit 22, a power switching element Q2 composed of a P-type MOS-FET as a voltage-driven switching element, a PNP-type transistor (bipolar transistor) Q3 as a current limiting control element, a first resistor 24 denoted by R1 in the figure, a second resistor 26 denoted by R2, a third resistor (resistive element in the present invention) 27 denoted by R3, and a capacitor (capacitive element in the present invention) 23 denoted by Cs in the figure.

In this case, the current detection resistor 21 is connected in series to the positive side power source line 4 in a subsequent stage of the input capacitor 8. The source as one main electrode of the power switching element Q2 is connected to the end of the current detection resistor 21 on the output capacitor 11 side. The drain as the other main electrode of the power switching element Q2 is connected to the end of the output capacitor 11 on the positive side power source line 4 side.

Also, one end of the first resistor 24 is connected to the gate as a control electrode of the power switching element Q2, and the collector as one main electrode of the transistor Q1 is connected to the other end of the first resistor 24. The emitter as the other main electrode of the transistor Q1 is connected to the negative side power source line 6, whereby the switch circuit 23 is connected between the gate of the power switching element Q2 and the negative side power source line 6 (the battery 2 on the side not connected to the power switching element Q2) via the first resistor 24. Then, the output of the ON/OFF signal circuit 22 is connected to the base as a control electrode of the transistor Q1.

Further, the collector as one main electrode of the transistor Q3 is connected to the gate of the power switching element Q2, and the emitter as the other main electrode of the transistor Q3 is connected to the positive side power source line 4 at the end of the current detection resistor 21 on the input capacitor 8 side. The second resistor 26 is connected between the source and gate of the power switching element Q2, and the third resistor 27 is connected between the positive side power source line 4 at the end of the current detection resistor 21 on the power switching element 2 side and the base as a control electrode of the transistor Q3. Then, the capacitor 28 is connected between the base and collector of the transistor Q3.

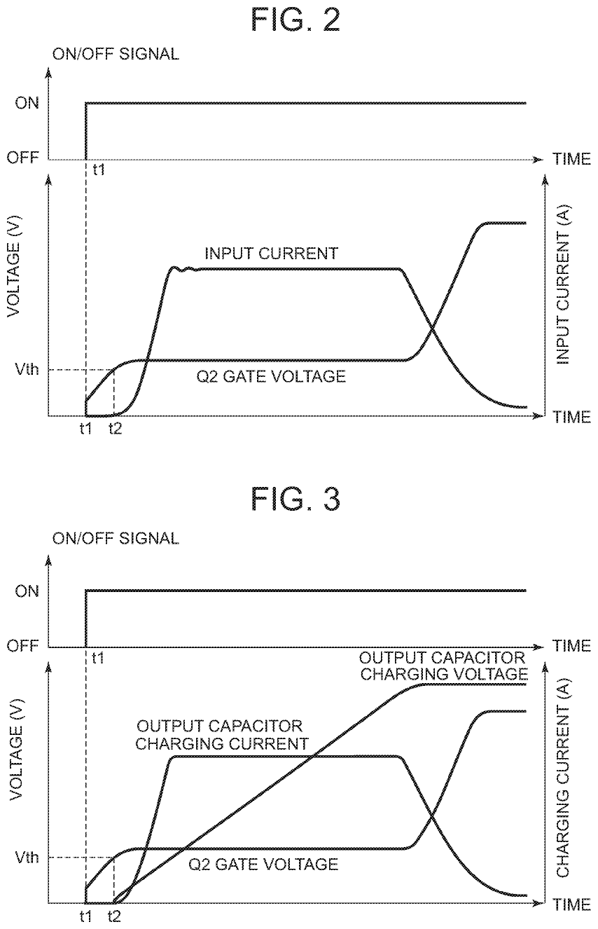

Next, the operation will be described. When a signal output from the ON/OFF signal circuit 22 is turned from OFF to ON at a time t1 in FIG. 2 upon starting the electric compressor, the transistor Q1 (NPN type bipolar transistor) is brought into an ON-state by this ON signal output. Since the collector of the transistor Q is connected to the gate of the power switching element Q2 through the first resistor 24 when the transistor Q1 is brought into the ON-state, the current from the battery 2 flows into the current detection resistor 21, the second resistor 26, the first resistor 24, and the collector of the transistor Q1 through the EMC filter circuit 7 after the transistor Q1 is turned ON. Incidentally, the input current in FIG. 2 is an input current which enters the EMC filter circuit 7.

On the other hand, since the capacitor 28 connected between the collector and base of the transistor Q3 is not charged in an initial state at the moment when the transistor Q1 is turned ON, the third resistor 27 and the second resistor 26 become a state close to being connected in parallel. Thus, the base of the transistor Q3 is applied with a voltage of a series portion of the current detection resistor 21—the parallel third and second resistors 27 and 26 which is obtained by dividing the DC voltage of the battery 2 by a series circuit with the first resistor 24. Since this voltage does not exceed a base forward voltage (ON voltage), no voltage exceeding the base forward voltage of the transistor Q3 is applied even between the gate and source of the power switching element Q2 connected in parallel with the second resistor 26.

Here, each resistance value of the current detection resistor 21, the second resistor 26, the third resistor 27, and the first resistor 24 is selected so that the voltage applied to the base of the transistor Q3 by their resistance voltage division becomes equal to or higher than the base forward voltage (ON voltage) within the range of the DC voltage to be used. Further, as the power switching element 2, there is selected one in which a threshold voltage Vth between the gate and source of the power switching element Q2 is higher than the base forward voltage (ON voltage) of the transistor Q3.

Then, since the gate-source voltage of the power switching element 2 does not exceed the threshold voltage Vth (the potential of the gate with respect to the source does not become lower than the threshold Vth), the power switching element Q2 remains OFF, so that no current flows between the source and drain of the power switching element Q2 and no charging current flows even through the output capacitor 11 yet.

On the other hand, after turning ON of the transistor Q1, the capacitor 28 starts to be charged via the third resistor 27 and the base of the transistor Q3. Thus, the charging voltage between the terminals of the capacitor 28 rises slowly, and the voltage applied to the second resistor 26 gradually approaches a value when the capacitor 28 is absent. Here, since the resistance values of the second resistor 26 and the first resistor 24 are selected such that the voltage applied between the gate and source of the power switching element Q2 becomes equal to or higher than the threshold voltage Vth within the range of the DC voltage used, the gate-source voltage of the power switching element Q2 exceeds the threshold voltage Vth at a time t2 in FIG. 2, FIG. 3 before long (the voltage of the gate with respect to the source of the power switching element Q2 becomes lower than the threshold Vth), and hence the power switching element Q2 is turned ON, so that the charging current gradually starts to flow from the battery 2 to the output capacitor 11 through the source-drain of the power switching element Q2. Incidentally, FIG. 3 shows the charging current and charging voltage of the output capacitor 11.

Further, when the charging current starts to flow between the source and drain of the power switching element Q2, the voltage applied across the current detection resistor 21 also rises. However, as the voltage applied across the current detection resistor 21 approaches the same voltage as the base forward voltage (ON voltage) of the transistor Q3, the current flowing through the second resistor 26 (charging current to the capacitor 28 decreases (the current flows through the second resistor 26 by subtraction of the voltage across the current detection resistor 21 from the base forward voltage of the transistor Q3). Therefore, the charging to the capacitor 28 is suppressed, and a rise in the gate-source voltage of the power switching element Q2 becomes more gradual.

That is, when the capacitor 28 is inserted between the base and collector of the transistor Q3, the gate-source voltage of the power switching element Q2 gradually increases while the transistor 3 is kept ON-state from immediately after the transistor Q1 is turned ON. After that, the operation shifts to a smooth current limiting operation according to the rise in the voltage across the current detection resistor 21 accompanying the rise in the charging current (rush current) to the output capacitor 11 to be described later.

As shown in FIG. 1, when the capacitor 28 is connected between the collector and base of the transistor Q3, the charging voltage between the terminals of the capacitor 23 gradually increases as described above, so that the gate-source voltage of the power switching element Q2 is not abruptly changed either, and the charging current to the output capacitor 11 is also suppressed from rising (FIG. 3).

As described above, since the rising of the inrush current (charging current to the output capacitor 11) is suppressed, even if the normal mode coils 13 and 14 are configured in the EMC filter circuit 7, the oscillation phenomenon of the input current is suppressed as shown in FIG. 2, and it is eliminated that the peak value of the input current exceeds a predetermined limit current value.

Incidentally, it is possible to suppress the oscillation phenomenon of the input current due to the inrush current even by inserting the capacitor between the gate and source of the power switching element Q2 (in parallel with the second resistor 26) as in the related art described above. However, in order to obtain the same effect, a capacitor capacitance of several tens of times is required as compared with the case where the capacitor 28 is inserted between the base and collector of the transistor Q3.

This is because, when the capacitor is inserted between the gate and source of the power switching element Q2, the capacitor is charged with the time constant of the inserted capacitor and the first resistor 24, so that the gate-source voltage of the power switching element Q2 also gradually rises, but the inrush current limiting operation is started only after the voltage across the current detection resistor 21 reaches the base forward voltage of the transistor Q, and the drain current flows all at once when the gate-source voltage of the power switching element Q2 exceeds the threshold Vth, so that in order to effectively suppress the oscillation phenomenon of the input current, there is a need to make the time constant with the first resistor 24 sufficiently large, that is to make the capacitance of the inserted capacitor sufficiently large.

Then, even after the OFF signal is output from the ON/OFF signal circuit 22, the electric charge is discharged through the second resistor 26 because of the large capacitance of the capacitor inserted between the gate and source of the power switching element 2. The output voltage is held for an unnecessarily long time until it falls below the threshold voltage Vth between the gate and source of the power switching element Q2 and the power switching element Q2 is turned OFF. However, by using the capacitor 28 between the base and collector of the transistor Q3, a discharge time becomes short due to the small capacitance of the capacitor 28, and hence such a problem is also solved.

When the charging current flows between the source and drain of the power switching element Q2, the voltage applied across the current detection resistor 21 rises, so that the base bias voltage of the transistor Q3 is raised to bring the transistor Q3 to an ON-state. When the transistor Q3 is turned ON, a current flows through the emitter-collector of the transistor Q3. Since this current flows to the collector of the transistor Q1 via the first resistor 24, the voltage of the gate portion of the power switching element Q2 rises, thereby limiting the charging current to the output capacitor 11 flowing from the source of the power switching element Q2 to the drain thereof. That is, a constant current operation is performed in which the current flowing through the current detection resistor 21 does not exceed a predetermined value, and the drain current of the power switching element Q2 is limited.

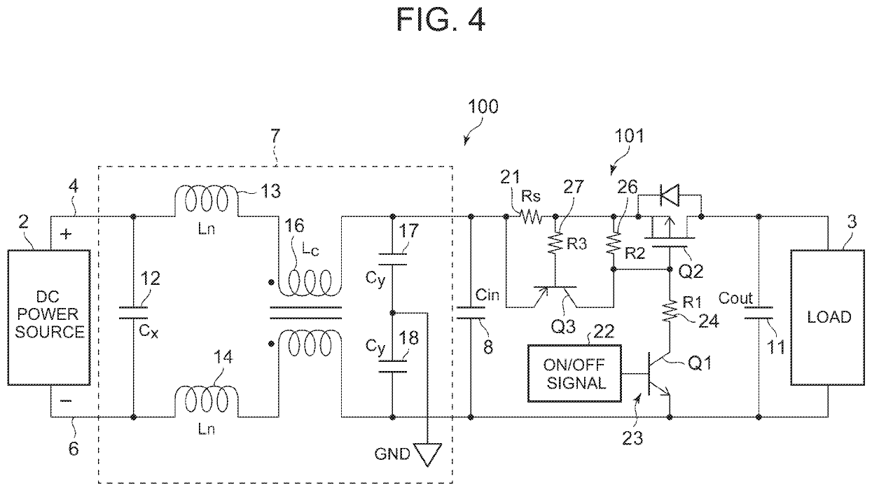

Here, when the capacitor 28 is not connected between the collector and base of the transistor Q3 as shown in FIG. 4, the signal output from the ON/OFF signal circuit 22 changes from OFF to ON at the time t1. Immediately after the transistor Q1 is turned ON, the voltage applied across the second resistor 26 exceeds the threshold voltage Vth of the gate-source voltage of the power switching element Q2, so that the power switching element Q2 is turned ON, and thereby the charging current flows from the battery 2 to the output capacitor 11 through the source-drain of the power switching element Q2 as an inrush current, and the rising of the current also becomes abrupt (FIG. 6).

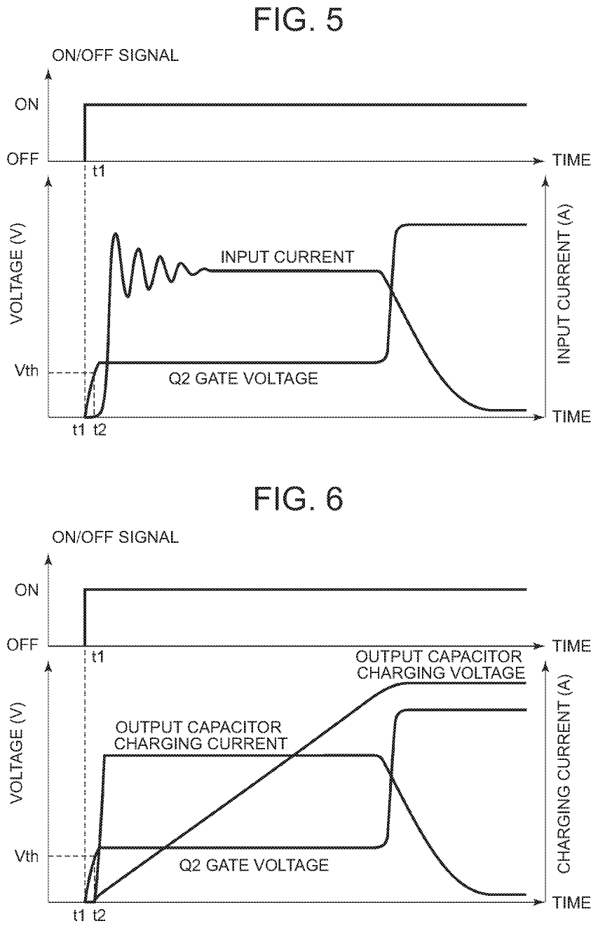

When a sudden rising inrush current flows, in the case where the normal mode coils 13 and 14 denoted by Ln in the figure such as the EMC filter circuit 7 are configured in the input section, the input current becomes an oscillation waveform as shown in FIG. 5 due to the resonance with the input capacitor 8, and hence the peak value of the input current exceeds a predetermined limit current value (the same applies also in the case where a parasitic inductance is included in an input current path from the DC power source).

As described above in detail, according to the present invention, the voltage at the base of the transistor Q3 changes according to the voltage generated across the current detection resistor 21, and the transistor Q3 adjusts the voltage at the gate of the power switching element Q2 to perform the constant current operation. Further, the third resistor 27 is connected between one end of the current detection resistor 21 and the base of the transistor Q3, and the capacitor 28 is connected between the base and collector of the transistor Q3. Therefore, the rise of the inrush current is suppressed, and even in the case where the EMC filter circuit 7 having the inductance component is provided as in the embodiment, the oscillation phenomenon of the input current is suppressed, and the exceeding of the peak value of the inrush current from the predetermined limit current value can be eliminated.

Particularly, since the capacitor 28 is connected between the base and collector of the transistor Q3, it is possible to suppress the rise of the inrush current with the capacitive element having the small value and to suppress the oscillation phenomenon of the input current.

In particular, the power source input circuit 1 of the present invention becomes an extremely suitable one in that since the capacitance of the capacitor 2E acting to hold the gate-source voltage of the power switching element Q2 may be a small value, the holding time of the output voltage when the supply of power is turned OFF is not excessively long either where the DC/DC converter 3 or the like of the control circuit for controlling the inverter of the vehicular inverter-integrated electric compressor is applied as the load as in the embodiment, so that the restriction on the ON/OFF operation time is satisfied without any trouble.

Incidentally, in the embodiment, the DC/DC converter constituting the control circuit (load) of the vehicular inverter-integrated electric compressor has been described by way of example. However, the inventions other than claim 6 are not limited thereto, and the present invention is effective for all devices to control the current from the DC power source to the load.

Further, in the embodiment, the P-type MOS-FET has been adopted as the power switching element Q2. However, the polarities of the power switching element Q2 and the transistors Q1 (NPN type) and Q3 (PNP type) are not limited to those in the embodiment. This can also be achieved by using an element having an opposite polarity as the negative side power source line 6 as for a connection location.

### DESCRIPTION OF REFERENCE NUMERALS

1 power source input circuit
2 battery (DC power source)
3 DC/DC converter (load)
4 positive side power source line
6 negative side power source line
7 EMC filter circuit (filter circuit)
9 current limiting circuit
11 output capacitor
21 current detection resistor
23 switch circuit
24 first resistor
26 second resistor
27 third resistor (resistive element)
28 capacitor (capacitive element)
Q1 transistor
Q2 power switching element
Q3 transistor (current limiting control element)

1. A power source input circuit which includes a power switching element connected between a DC power source and a load and changes a voltage of a control electrode of the power switching element to control a current from the DC power source to the load, comprising:
a current detection resistor which detects the current with a voltage generated at both ends thereof due to an inrush current; and
a current limiting control element having a control electrode and a pair of main electrodes whose one main electrode is connected to the control electrode of the power switching element,
wherein a voltage of the control electrode of the current limiting control element changes according to the voltage generated across the current detection resistor, and thereby the current limiting control element adjusts the voltage of the control electrode of the power switching element to allow a constant current operation to be performed, and
wherein a resistive element is connected between one end of the current detection resistor and the control electrode of the current limiting control element, and a capacitive element is connected between the control electrode of the current limiting control element and the one main electrode thereof.

2. The power source input circuit according to claim 1, wherein the power switching element is a voltage-driven switching element having a gate as the control electrode,
wherein the current limiting control element is a bipolar transistor having a base as the control electrode and a collector and an emitter as the main electrodes, and
wherein the collector as the one main electrode of the current limiting control element is connected to the control electrode of the power switching element, and the capacitive element is connected between the base and collector of the current limiting control element.

3. The power source input circuit according to claim 1, including:
a switch circuit connected via a first resistor between the control electrode of the power switching element and the DC power source on the side non-connected to the power switching element, and
a second resistor connected between one main electrode of the power switching element and the control electrode thereof.

4. The power source input circuit according to claim 3, wherein immediately after the switch circuit is made conductive, the voltage of the control electrode of the power switching element does not reach an ON voltage of the power switching element, and the voltage of the control electrode of the current limiting control element reaches an ON voltage of the current limiting control element.

5. The power source input circuit according to claim 1, including a filter circuit having an inductance component.

6. An inverter-integrated electric compressor for a vehicle, having the power source input circuit according to claim 1, and a control circuit to control an inverter as the load.

7. The power source input circuit according to claim 2, including:
a switch circuit connected via a first resistor between the control electrode of the power switching element and the DC power source on the side non-connected to the power switching element, and
a second resistor connected between one main electrode of the power switching element and the control electrode thereof.

8. The power source input circuit according to claim 2, including a filter circuit having an inductance component.

9. The power source input circuit according to claim 3, including a filter circuit having an inductance component.

10. The power source input circuit according to claim 4, including a filter circuit having an inductance component.

11. An inverter-integrated electric compressor for a vehicle, having the power source input circuit according to claim 2, and a control circuit to control an inverter as the load.

12. An inverter-integrated electric compressor for a vehicle, having the power source input circuit according to claim 3, and a control circuit to control an inverter as the load.

13. An inverter-integrated electric compressor for a vehicle, having the power source input circuit according to claim 4, and a control circuit to control an inverter as the load.

14. An inverter-integrated electric compressor for a vehicle, having the power source input circuit according to claim 5, and a control circuit to control an inverter as the load.
